(19) United States
(12) Patent Application Publication
(10) Pub. No.: US 2018/0221996 A1
(43) Pub. Date: Aug. 9, 2018

(54) PROCESS FOR THE MANUFACTURE OF FLUX COMPOSITIONS

(71) Applicant: SOLVAY SA, Brussels (BE)

(72) Inventor: Stefanie VOLMER, Garbsen (DE)

(21) Appl. No.: 15/749,662

(22) PCT Filed: Aug. 3, 2016
(86) PCT No.: PCT/EP2016/068507

§ 371 Date: Feb. 1, 2018

(30) Foreign Application Priority Data
Aug. 4, 2015 (EP) 15179732.1

(51) Int. Cl. B23K 35/362; B23K 35/36; B23K 1/20

(52) U.S. Cl. CPC B23K 35/362; B23K 35/3613; H05K 3/3489; B23K 35/3607; B23K 1/203; B23K 35/361

(57) ABSTRACT

The present invention concerns a process for the manufacture of flux compositions, flux compositions obtainable by the process according to the invention, aluminum or aluminum alloy parts at least partially coated with the flux composition manufactured by the process, and a brazing process and brazed metal object obtainable by said process.

The present invention concerns a process for the manufacture of flux compositions, flux compositions obtainable by the process according to the invention, aluminum or aluminum alloy parts at least partially coated with the flux composition manufactured by the process, and a brazing process and brazed metal object obtainable by said brazing process. Fluxes are inorganic compounds which are used in brazing, soldering and welding of aluminum parts and/or aluminum alloy parts in order to remove the oxide layer on the parts to enable effective joining of the parts. Often, the fluxes are dispersed in liquid carriers (also denoted as dispersion agent), optionally in the presence of additives, prior to being applied to the aluminum or aluminum alloy surface. After drying, the parts are assembled, brazed, soldered or welded, the applied flux melting and removing the oxide layer of the aluminum or aluminum alloy in the process.

The components of the flux composition need to be compatible with the brazing, soldering or welding conditions. Also, there are multiple challenges to be addressed when formulating a flux composition: The dispersion needs to be sufficiently stable, i.a. the flux dispersed in the dispersion agent should not settle too fast, thus creating a cake layer which is difficult to resuspend. If a cake forms to any extent, this should at least be able to be resuspended with minimum effort. The composition needs to be sufficiently fluid in order to be applicable to the metal parts with spraying, dipping, rolling, canula application, printing or painting techniques, with enough viscosity to adhere, and a balance between viscosity and fluidity such that enough, but not too much (to avoid overload and economic disadvantage), flux is applied. In particular the aspect of dispersion stability is a matter of concern. Often, the flux compositions contain a binder to enhance adherence of the flux to the metal parts, in particular the aluminum or aluminum alloy parts.

EP1287941B1 describes a process for the preparation of a flux composition comprising a binder, wherein half of the total amount of solvent, a binder and a thixotropic agent are provided as mixture, and a flux is added with stirring, after which the second half of the solvent is added.

It has been shown surprisingly that, in the production of a flux composition comprising a binder, it is advantageous to control the temperature of the mixture to a temperature of equal to or less than 70° C., preferably equal to or less than 60° C., and more preferably of equal to or less than 50° C. during and after addition of the binder in the production process. A temperature of equal to or less than 30° C. has been proven to be most advantageous. The composition displays an extended stability time, with reduced tendency of flux settling, reduced tendency of gelling (which can be, for example, the result of partial polymerization) of the binder or other components, and enhanced stability of the composition with respect to homogeneity.

Accordingly, the invention concerns a process for the manufacture of a flux composition, comprising at least one binder, at least one dispersion agent and at least one flux, wherein a temperature of equal to or lower than 70° C., preferably equal to or lower than 60° C. and even more preferably of equal to or lower than 50° C. is maintained during and after addition of the binder in the production process. A temperature of equal to or less than 30° C. has been proven to be most advantageous.

In the present invention, designations in singular are in intended to include the plural; “a binder” is intended to denote also “more than one binder” or “a plurality of binders”.

In the context of the present invention, the term “comprising” is intended to include the meaning of “consisting of”.

The flux used for the manufacture of flux compositions according to the present invention is a flux suitable for brazing, soldering or welding, preferably brazing, of aluminum parts or aluminum alloy parts. Fluxes in the sense of the present invention, are chemicals able to remove layers on metal surfaces, such as oxide layers, to make them accessible to metallurgical processes. In particular, fluxes in the sence of the present invention are suitable to remove an oxide layer from aluminum or aluminum alloy surfaces, or other metallic surfaces, before these are subject to welding, soldering or brazing processes. Preferably, the flux comprises at least one compound selected from the group consisting of potassium fluoroaluminate, cesium fluoroaluminate, alkali fluorozincate, preferably potassium fluorozincate, and alkali fluorosilicate, preferably K₂SiF₆. Generally, the content in K₃AlF₆ in a flux comprising potassium fluoroaluminate is low, preferably equal to or less than 5% by weight, more preferably equal to or less than 3% by weight, even more preferably equal to or less than 1% by weight. Most preferably, K₃AlF₆ is absent in the flux comprising potassium fluoroaluminate, which is equal to 0 weight % of K₃AlF₆ in the flux comprising potassium fluoroaluminate. The potassium fluoroaluminates can be present partially or completely in the form of their hydrates; e.g., K₂AlF₅ can be present partially or completely in the form of K₂AlF₅.H₂O. It is known that K₂AlF₅ exists in a form which may be rehydrated, and it exists in a form which is irreversibly dehydrated. Each of the forms or a mixture of them in any desired ratio can be present in the fluxes. Details concerning their manufacture and use are given in U.S. Pat. No. 5,980,650. For example, a precipitated K₂AlF₅ raw product is dried in a drier at 570° C., residence time 0.5 seconds. The resulting product contains irreversibly dehydrated K₂AlF₅. In one embodiment, the flux comprises or consists of K₂AlF₅. Such a flux may contain K₂AlF₅ and/or its hydrate, K₂AlF₅.H₂O. The total content of K₂AlF₅ is preferably equal to or higher than 95% by weight. The preferred content of K₃AlF₆, if any, is as given above, preferably equal to or lower than 2% by weight.

In a further embodiment, the flux comprises or consists of KAlF₄ and K₂AlF₅ and, if present, their hydrates. Often, such a flux consists essentially of a mixture of KAlF₄ and K₂AlF₅ or their hydrates; “essentially” denotes preferably that their sum constitutes equal to or more than 95% by weight, more preferably, equal to or more than 98% by weight of the flux. Notably, at most 2% by weight of such a flux are constituted by K₃AlF₆ preferably equal to or less than 2% by weight, and most preferably equal to or less than 1% by weight including 0% by weight. The weight ratio between KAlF₄ (including any hydrate if present) and K₂AlF₅ (including any hydrate if present) is very flexible. It can be 1:99 to 99:1. Often, it is in the range of 1:10 to 10:1. A flux comprising 10 to 40% by weight of K₂AlF₅, K₂AlF₅.H₂O or any mixtures thereof, the balance to 100% by weight being essentially KAlF₄ is very suitable.

In yet another embodiment, the flux comprises or consists of cesium fluoroaluminate, in the form of CsAlF₄, Cs₂AlF₅, Cs₃AlF₆, their hydrates and any mixture of two, three or more thereof. CsAlF₄ and Cs₂AlF₅, or their hydrates, and mixtures thereof are preferred. CsAlF₄ is most preferred. Often, the flux comprising cesium fluoroaluminate, preferably CsAlF₄, further comprises K₂AlF₅ and optionally KAlF₄. Fluxes containing potassium fluoroaluminate and cesium cations, e.g. in the form of cesium fluoroaluminate, as described in U.S. Pat. No. 4,670,067 and U.S. Pat. No. 4,689,062 are also very suitable. Those cesium-containing basic fluxes are especially suitable to solder, weld or, in particular, braze aluminum-magnesium alloys. The weight ratio of KAlF₄ and K₂AlF₅ is preferably as described above. The Cs content is, calculated as content in CsF, between 2 and 74 mol-%. The sum of KAlF₄, K₂AlF₅ and the cesium fluoroaluminate compound or compounds, including any hydrate, is preferably equal to or greater than 95% by weight, more preferably equal to or more than 98% by weight. The content of K₃AlF₆ is preferably equal to or less than 2% by weight, and most preferably equal to or less than 1% by weight including 0% by weight.

In a further embodiment, the flux comprises or consists of alkali fluorozincates, preferably KZnF₃. Such fluxes are disclosed, for example, in WO99/48641, WO2009153312 and WO01/74715.

In another embodiment, the flux comprises or consists of alkali hexafluorosilicates, in particular K₂SiF₆ or Cs₂SiF₆ or mixtures thereof. Such fluxes are disclosed, for example, in WO00/73014.

Fluxes comprising Li ions as additive are also preferred fluxes according to the present invention, in particular fluxes which are based on K₂AlF₅, precursors of K₂AlF₅, or hydrates of the foregoing as disclosed in WO2011/098120 and WO2010/060869. Precursors of K₂AlF₅ include KZnF₃, K₂SiF₆, Cs₂AlF₆, their hydrates and mixtures of the foregoing. Suitable sources of Li ions as additives in such fluxes are, for example, LiF, Li₃AlF₆, LiOH, Li oxalate or Li₂CO₃. Fluxes containing Li ions often display reduced corrosivity of their brazing residue.

In another aspect, the flux comprised in the flux composition is a lithiumfluoroaluminate, in particular Li₃AlF₆. In a one aspect, the flux essentially consists of the lithiumfluoroaluminate,

Fluxes which contain potassium fluoroaluminate and at least one magnesium-compatibilizing compound selected from the group consisting of metal fluorometallates with the proviso that potassium fluoroaluminate is essentially present as monopotassium tetrafluoroaluminate are also well suited for the process according to the present invention. Such flux mixtures are disclosed, for example, in PCT/EP2014/078159. Cesium fluoroaluminates, potassium fluorozincates and cesium fluorozincates are the preferred metal fluorometallates in these fluxes.

Fluxes having a specific particle size, as disclosed in WO2011110532, are also suitable for the process according to the present invention. Often, the addition of such fluxes can improve certain parameters, such as viscosity and flux settling, in flux compositions as manufactured by the process according to the present invention. In one aspect, the complete flux added to the composition has the disclosed particle size. In another aspect, the flux with the specified particle size is added as a fraction of the overall flux.

Fluxes comprising a fundamental flux, wherein the fundamental flux comprises from 80 mol % to 100 mol % KAlF₄, preferably wherein the content of K₃AlF₆ in the flux is equal to or lower than 2 mol % including 0 mol %, the content of free KF in the flux is lower than 0.2% by weight including 0% by weight, wherein the flux further comprises from 0.1 to 20 weight % relative to the total weight of the flux of at least one additive salt, wherein the at least one additive salt comprises at least one anion selected from the group consisting of F⁻, CO₃²⁻, O²⁻, nitrate, phosphate, borate, metaborate and oxalate, and at least one cation selected from the group consisting of earth alkali metal cations, as disclosed in PCT/EP2015/055003 are also well suited for the process according to the present invention. Fluxes comprising CaF₂, MgF₂ and Li₃AlF₆, further comprising at least one fluoride selected from the group consisting of SrF₂ and BaF₂ and optionally LiF, with the proviso that, if LiF is comprised, the weight ratio between LiF and Li₃AlF₆ is in a range of from 1:1 to 1:99 are, as disclosed in PCT/EP2015/055425 are another class of fluxes which are well suited for the process according to the present invention.

In another preferred embodiment, brazing fluxes comprising or consisting of, relative to the total weight of the brazing flux, equal to or more than 80% by weight of KAlF₄ and equal to or more than 1% by weight of CsAlF₄, and equal to or more than 2% by weight of a second component selected from the group consisting of Li₃AlF₆, CaF₂, CaCO₃, MgF₂, MgCO₃, SrF₂, SrCO₃, BaF₂, BaCO₃, and mixtures of two or more of said second components as disclosed in PCT/EP2015/055003 are another class of fluxes which are well suited for the process according to the present invention.

In a most preferred embodiment, the flux consists of KAlF₄ and K₂AlF₅, preferably in a weight ratio of about 4:1, which is known as Nocolok®, KZnF₃ known as Nocolok® Zn Flux, potassium hexafluorosilicate such as Nocolok® CB Flux, or KAlF₄ and K₂AlF₅ and Li additive also known as Nocolok® Li Flux.

Generally, the flux composition obtainable by the process according to the present invention is suitable for various application methods, wherein the flux composition is applied to aluminum or aluminum alloy parts to be assembled and welded, soldered, or, preferably, brazed. The flux composition may be painted, printed, for example by pad printing or tampon printing (tampography), sprayed or be applied by dipping of the parts to be joined, in particular brazed.

According to the present invention, a binder is comprised in the flux composition. Binders improve, for example, the adhesion of the flux mixture after their application on the parts to be joined, in particular brazed. Suitable binders can be selected, for example from the group consisting of organic polymers. Such polymers are physically drying (i.e., they form a solid coating after the liquid is removed), or they are chemically drying (they may form a solid coating e.g. under the influence of chemicals, or under the influence of oxygen or light which causes a cross linking of the molecules), or both. Suitable polymers include polyolefines, e.g. butyl rubbers, polyurethanes, resins, phthalates, polyacrylates, polymethacrylates, vinyl resins, epoxy resins, nitrocellulose, polyvinyl acetates, polysaccharide acetates, such as acetylated starch or cellulose, or polyvinyl alcohols. Particularly preferred are polyurethane binders.

Polyurethane binders are often selected in combination with polar dispersion agents, such as water or alcohols. Dispersion agents will be further explained below. Particularly preferred binders are aliphatic polyester polyurethane binders. Often, the binder is removed/pyrolyzed/combusted in an amount of equal to or more than 90%, preferably equal to or more than 95%, and even more preferably equal to or more than 98% when a dry film of the binder or dried flux composition is heated to a temperature of 450° C.

Often, binders are provided to the process in the form of a binder composition comprising at least one binder and at least one solvent. Often, the at least one solvent comprised in the at least one binder composition is identical with the at least one dispersion agent which is added to the flux composition manufacturing process as the liquid carrier.

The term “dispersion agent” denotes a liquid carrier in which the flux is dispersed. The binder and/or additives are also dispersed or, where applicable, solved in the dispersion agent. Suitable dispersion agents are, for example, water, water-free organic liquids or aqueous organic liquids. Preferred liquids are those that have a boiling point at ambient pressure (1 bar abs) of equal to or lower than 350° C. Dispersion agents that are preferred are water, in particular deionized or demineralized water, mono-, di- or tribasic aliphatic alcohols, especially those with 1 to 4 carbon atoms, e.g. methanol, ethanol, isopropanol, or ethylene glycol, or glycol alkyl ethers, wherein alkyl preferably denotes linear aliphatic C1 to C4 alkyl or C3 to C4 branched alkyl. Non-limiting examples are glycol monoalkyl ethers, e.g. 2-methoxyethanol or diethylene glycol, or glycol dialkylethers, for example, dimethyl glycol (dimethoxyethane), N-Methyl-2-pyrrolidon, 3-Methoxy-3-methyl-1-butanol and 1-Methoxy-2-propyl acetate. Mixtures comprising two or more of the dispersion agents are also suited very well. Isopropanol or mixtures containing isopropanol are especially suitable. The most preferred dispersion agent is water, especially de-ionized water. The term “dispersion agent” also denotes mixtures of two or more dispersion agents. While fluxes for use of manufacturing flux compositions according to the present invention generally are essentially insoluble in the dispersion agent, this does not exclude that a part of the flux composition can be dissolved in the liquid; this may be the case especially when water or aqueous organic liquids are contained in the flux composition.

The term “solvent” denotes a liquid in which the binder, and optionally other additives, are solved. In principle, solvents are often selected from the same list as the dispersion agent. Often, the one or more solvents and one or more dispersion media comprised in the flux composition are identical.

The binder often is added in the process according to the present invention in the form of a binder composition which comprises the binder, or binders, and a solvent, or solvents or dispersion agent, or dispersion agents.

The term “binder composition” denotes a composition comprising a binder, or mixtures of two or more binders, as described above, and a solvent, wherein “solvent” also denotes mixtures of two or more solvents, or a dispersion agent, wherein “dispersion agent” also denotes a mixtures of two or more dispersion agents. This terminology depends on the interaction of the binder and the solvent or dispersion agent; if the binder is solved in the liquid, the binder composition comprises a solvent. If the binder is dispersed in the liquid, the binder composition comprises a dispersion agent. Generally, the solvent or dispersion agent comprised in the binder composition is the same as described above in the definition of “dispersion agent”. In a particularly preferred embodiment, the solvent or dispersion agent in the binder composition is the same as the dispersion agent in which the flux is dispersed in the flux composition manufacturing process. In a preferred aspect, the solvent and/or dispersion agent comprised in the binder composition is water, preferably de-ionized water. In a most preferred aspect, the binder composition comprises water as solvent and/or dispersion agent and a polyurethane binder, preferably polyester polyurethane, as binder. Often, the solids content of the binder is equal to or greater than 10 weight %, more preferably equal to or greater than 12 weight % and even more preferably equal to or greater than 14 weight %. The solids content of the binder further often is equal to or less than 45 weight %, more preferably equal to or less than 42 weight % and even more preferably equal to or less than 40 weight %.

In the process according to the present invention, other additives which improve the properties of the composition, for example, suspension stabilizers, surfactants, especially nonionic surfactants, e.g. Antarox BL 225, a mixture of linear C8 to C10 ethoxylated and propoxylated alcohols, other methoxylated, ethoxylated and/or propoxylated alcohols such as (2-Methoxymethylethoxy)propanol, polysiloxanes, polyether modified siloxanes, thickeners, e.g. methyl but ether or polyurethanes, in particular polyester polyurethanes , thixotropic agents, e.g. gelatine or pectines, or a wax as described in EP-A 1808264, or defoamers such as polyoxyethylene stearylether can be added to the flux composition during the process. In one aspect of the present invention, the one or more additives are comprised in the binder or binder composition which is added in the process. In another embodiment, the one or more additives are added individually or together to the flux composition at one or more instants during the process. (2-Methoxymethylethoxy)propanol and/or polyoxyethylene stearylether as additive are most preferred additives. The content of additives which improve the properties of the composition in the flux composition, if present, usually is equal to or larger than 0.1 weight % of the final flux composition, but may, in other aspects, be equal to or larger than 0.2 weight % or even equal to or larger than 0.3 weight %, depending on the flux composition and the properties thereof. The content of additives which improve the properties of the composition in the flux composition, if present, usually is equal to or less than 5 weight % of the final flux composition, but may, in other aspects, be equal to or less than 2 weight % or even equal to or less than 1 weight %, depending on the flux composition and the properties thereof.

The term “homogenizing” in the present invention intends to denote the achievement of a homogenous flux composition in which liquid and solid components are mixed such they are evenly distributed in the composition.

The content of flux, wherein “flux” also denotes mixtures of two or more fluxes, in the final flux composition generally is equal to or greater than 0.75% by weight. Preferably, it is equal to or greater than 1% by weight. More preferably, the flux content in the composition is equal to or greater than 5% by weight, very preferably, equal to or greater than 10% by weight of the total flux composition. Generally, the content of the modified flux in the composition is equal to or lower than 70% by weight. Preferably, it is equal to or lower than 50% by weight. A flux content in the final flux composition of from 20 to 45% by weight of the total weight of the flux composition is especially preferred.

The content of binder, wherein “binder” also denotes mixtures of two or more binders, in the final flux composition generally is equal to or greater than 0.1% by weight. Preferably, it is equal to or greater than 0.5% by weight. More preferably, the binder content in the composition is equal to or greater than 0.8% by weight, very preferably, equal to or greater than 1% by weight of the total flux composition. Generally, the content of the binder in the flux composition is equal to or lower than 40% by weight. Preferably, it is equal to or lower than 30% by weight, and most preferably lower than 20% by weight. In one preferred embodiment, the binder content in the composition is from 1 to 15% by weight.

The content of thickener, when present, wherein “thickener” also denotes mixtures of two or more thickeners, in the composition generally is equal to or greater than 0.1% by weight. Preferably, it is equal to or greater than 0.2% by weight. Most preferably, the thickener content in the composition is equal to or greater than 0.3% by weight. Generally, the content of the thickener in the composition is equal to or lower than 10% by weight. Preferably, it is equal to or lower than 7% by weight, and most preferably lower than 5% by weight. In one preferred embodiment, the thickener content in the final flux composition is from 0.1 to 4% by weight. The one or more thickeners are usually selected, for example, from the group consisting of polyurethanes, acrylates, polysaccharides, for example cellulose, cellulose derivatives such as cellulose ethers, starch or starch derivatives, guar gum, methyl butyl ether and ethoxylated alcohols.

The flux composition can optionally contain further fluxing additives, for example, thixotropic agents, filler metals or filler alloys.

The term “flux composition” also includes the term “paint flux composition”, a term which is often used in relationship with such flux composition. The flux compositions according to the present invention are not restricted, though, to any application method, such as, for example, “painting”, but can, as is explained above, also be sprayed or applied by other methods, for example by printing, in particular through pad printing or tampon printing (tampography). Viscosity and other characteristics of the flux composition are suitably adjusted to the application method.

In one embodiment, the flux composition comprises a filler metal or filler metal alloy or a plurality of one or both, in the form of a fine powder. When aluminum parts are brazed, the filler metal often is silicon, or the filler alloy often is an Al/Si alloy. The content of the one or more filler metals or filler alloys, if present, often is equal to or more than 0.5 weight %, based on the total weight of the flux composition, preferably equal to or more than 1 weight %, and even more preferably equal to or more than 5 weight %. The content of the one or more filler metals or filler alloys, if present, often is equal to or less than 50 weight %, based on the total weight of the flux composition, preferably equal to or less than 40 weight %, and even more preferably equal to or less than 30 weight %.

In another embodiment, the paint flux composition comprises one or more thixotropic agents. The thixotropic agent, or a plurality thereof, often is selected from the group consisting of gelatine, pectines, acrylates and polyurethanes, but can also be any other agent influencing the thixotropy of the flux composition in the desired manner and being compatible with the other ingredients, the fluxing and brazing conditions. The content of the one or more thixotropic agents, if present, often is equal to or more than 0.5 weight %, based on the total weight of the flux composition, preferably equal to or more than 1 weight %, and even more preferably equal to or more than 5 weight %. The content of the one or more thixotropic agents, if present, often is equal to or less than 50 weight %, based on the total weight of the flux composition, preferably equal to or less than 40 weight %, and even more preferably equal to or less than 30 weight %.

In the process for the manufacture of a flux composition, comprising at least one binder, at least one dispersion agent and at least one flux, a temperature of equal to or lower than 70° C., preferably equal to or lower than 60° C. and even more preferably of equal to or lower than 50° C. is maintained during and after addition of the binder. A temperature of equal to or lower than 30° C. is most particularly preferred. Generally, a temperature of equal to or higher than 0° C., preferably equal to or higher than 5° C. and even more preferably of equal to or higher than 10° C. is maintained during and after addition of the binder. In one aspect, it is preferred that a temperature of from 10° C. to 50° C. is maintained during and after addition of the binder. In another, even more preferred aspect, a temperature of from 10° C. to 30° C. is maintained during and after addition of the binder. Compositions manufactured according to the process of the present invention display an extended stability time, with reduced tendency of flux settling, reduced tendency of gelling (which can be the result of partial polymerization) of the binder or other components, and enhanced stability of the composition with respect to homogeneity. The extended stability time further is advantageous in view of possibility to store and transport the compositions. Parts to be brazed can be coated with the flux composition more evenly and with dosage which can be controlled effectively, resulting in lower cost and stable, optimized brazing results. Risk of clogging of application equipment is reduced, which results in reduced application line downtime, maintenance cost and equipment savings. Even compositions which are manufactured for immediate use profit from the process as unexpected downtime of the subsequent or upstream equipment will have a reduced tendency to result in clogged lines or equipment of the flux composition line, and the quality of the compositions can remain essentially stable in such situations. In case that solids settle in the flux composition, the cake formed usually can be resuspended with minimum effort.

The invention also concerns a flux composition obtainable through the process according to the present invention, and the respective embodiments and aspects.

In one embodiment E1 of the present invention, the process for the manufacture of a flux composition comprises
a) Mixing at least one flux and at least one dispersion agent
b) Homogenizing the mixture obtained by step a)
c) Controlling the temperature of the mixture obtained by step b) such that a temperature of equal to or lower than 50° C., preferably equal to or lower than 60° C. and even more preferably of equal to or lower than 50° C. is achieved or maintained
d) Adding at least one binder to the mixture obtained by the foregoing steps at a temperature of equal to or lower than 70° C., preferably equal to or lower than 60° C. and even more preferably of equal to or lower than 50° C.

According to this embodiment, in step a), the at least one flux is mixed with the at least one dispersion agent in step a). Often, the at least one flux is added to the at least one dispersion agent. The amount of dispersion agent, which includes also “mixtures of one or more dispersion agents” which is used in the step a), is selected according to the other factors of the process, such as viscosity of the dispersion agent, total amount of flux in the final flux composition, and others. Generally, the amount of dispersion agent used in step a) is equal to or more than 20 weight % of the total amount of dispersion agent contained in the final flux composition, preferably equal to or more than 30 weight % and even more preferably equal to or more than 40 weight % of dispersion agent contained in the final flux composition. Often, the amount of dispersion agent used in step a) is equal to or less than 95 weight % of the total amount of dispersion agent contained in the final flux composition, preferably equal to or less than 90 weight % and even more preferably equal to or less than 85 weight % of dispersion agent contained in the final flux composition. Generally, step a) is performed under active mixing of the dispersion agent and flux, for example with stirrers or other homogenizing apparatus. In one aspect, the mixing is performed using the same homogenizing or stirring apparatus as in step b). In another aspect, which depends also on other factors, such as particle size of the flux, the mixing in step a) is performed with a different stirring apparatus than in step b). According to this embodiment, in step b), the mixture obtained in step a) is homogenized. Homogenizing is performed employing mixers which can be chosen from a variety of mixers commonly used in mixing and homogenizing of solid-liquid-mixtures in chemical process engineering. Examples include pitch blade turbines, flat blade turbines, paddle stirrer, propellers, impellers, such as axial flow impellers, cross-beam, grid, anchor or blade stirrers, rotor-stator stirrers, hollow stirrers, for example hollow tube stirrer, and disperser disks. In one embodiment, stirrers exerting shear force are preferred. Stirrers operating according to the rotor-stator-principle are especially preferred, such as Ultra-Turrax(R) (from the manufacturer IKA) stirrers, or Dispeax-reactors of the manufacturer Jahn and Kunkel. In another preferred aspect, the mixture is homogenized in step b) by wet milling. Often, in this aspect, the particle size of the solids in the suspension is not or not substantially reduced by using stirrers which exert shear force, as the step is rather focused on the homogenization, although reduction of the particle size is not excluded. This technique often can alter the particle surface morphology. In step c) according to this embodiment, the temperature of the mixture obtained by step b) is controlled such that a temperature of equal to or lower than 70° C., preferably equal to or lower than 60° C. and even more preferably of equal to or lower than 50° C. is achieved or maintained. A temperature of equal to or lower than 30° C. is most particularly preferred. Generally, a temperature of equal to or higher than 0° C., preferably equal to or higher than 5° C. and even more preferably of equal to or higher than 10° C. is achieved and maintained in step c). In one aspect, it is preferred that a temperature of from 10° C. to 50° C. is achieved and maintained in step c). In another more preferred aspect, a temperature of from 10° C. to 30° C. is achieved and maintained in step c). The temperature is achieved by active cooling or heating, or by passively letting the mixture adapt to a temperature within the given range. In one embodiment, the mixture obtained is step b) is stirred during step c); in another embodiment, the mixture obtained by step b) is rested during step b). If in step c), the mixture is stirred, the same or a different stirring technique can be applied as in step b). Step c) has proven to be critical in the process according to the present invention, as the mixture exhibits a less stable quality when the binder is added to the mixture at a temperature higher than specified. Temperature control is especially critical when the homogenizing in step b) has introduced kinetic energy into the mixture, resulting in a higher temperature of the mixture. In step d) of the process according to this embodiment, at least one binder is added to the mixture obtained by the foregoing steps wherein a temperature of equal to or lower than 70° C., preferably equal to or lower than 60° C. and even more preferably of equal to or lower than 50° C. is maintained during the addition. Generally, a temperature of equal to or higher than 0° C., preferably equal to or higher than 5° C. and even more preferably of equal to or higher than 10° C. is maintained in step d). In one aspect, it is preferred that a temperature of from 10° C. to 50° C. is maintained in step d). The temperature is controlled by actively cooling or heating the mixture. Generally, the mixture is stirred during step d). In step d), the same stirring technique can be used as for step b) and/or c). In a particular aspect, in step d) a stirrer is used which does not exert shear force. The binder is added in step d) either as binder or as binder composition. In one aspect, if a binder composition comprising at least one binder is added to the mixture in step d), the binder composition comprises the solvent or dispersion agent which is the same as the dispersion agent used in step a). In another aspect, if a binder composition comprising at least one binder is added to the mixture in step d), the binder composition comprises the solvent or dispersion agent which is different from the dispersion agent used in step a). The binder content in the binder composition, if used, is selected such that the overall binder content in the final flux composition is reached, while also taking into account the final content of the dispersion agent and/or solvent in the flux composition. The final content of the dispersion agent and/or solvent in the flux composition is calculated by the sum of flux, binder, optional additives (such as thickeners, thixotropic agents, brazing additives such as filler, surfactants and the like), where the dispersion agent, together with any solvent, make up the difference to 100 weight %. In one aspect of the present invention, in particular when the at least one binder is added to the mixture in step d) without being solved or dispersed in at least one dispersion agent and/or at least one solvent, dispersion agent and/or solvent may be added separately to achieve the desired final contents of binder, flux, additives and at least one dispersion agent and/or at least one solvent. According to one aspect of the process of the current embodiment, the optionally present organic additives, such as surfactants and/or suspension stabilizers, are comprised in the dispersion agent used in step a). According to one aspect of the process of the current embodiment, the optionally present organic additives, such as surfactants and/or suspension stabilizers, are comprised in the binder or binder composition, if present, which is added in step d). According to another aspect of the process of the current embodiment, the optionally present organic additives, such as surfactants and/or suspension stabilizers, are added in step d) during, before or after the addition of the binder or the binder composition. Optionally, the process according to the present embodiment comprises a step e), wherein after addition of all components of the flux composition, the mixture is homogenized, preferably by a stirrer stirrers exerting shear force, wherein stirrers operating according to the rotor-stator-principle are especially preferred, while observing the temperature range. In another aspect, in optional step e) a stirrer is used which does not exert shear force. It is important that during the optional step e), the temperature of the flux composition is maintained according to the ranges given above for step c) and d). According to yet another aspect of the process of the current embodiment, the optionally present organic additives, such as surfactants and/or suspension stabilizers, are added in step a) during, before or after the addition of the flux to the dispersion agent. In one aspect of the present invention, one or more solid additives are added to the mixture during the process. Such a solid additive can, for example, be another flux which modulates the brazing characteristics of the flux composition, for example a cesiumaluminumfluoride complex or a lithium compound. The solid additive can be added to the process as a solid, or as dispersion in a suitable dispersion agent, which is the same as described above. Preferably, the solid additive is added in the process in the form of a dispersion, even more preferably wherein the dispersion has been manufactured using a stirrer with rotor-stator-principle. The solid additive or its dispersion can be added before, during or after each of steps a) to d) or optionally e), as long as the temperature is not exceeded as defined above for steps c) and d). In one aspect, the process can include another step wherein, after addition of all components, and finalized mixing, the composition is filtered, for example through a 300 mesh filter. In one aspect, during the one or more mixing or homogenization steps, care should be taken that as little air as possible if mixed into the mixture in order to avoid foam formation. The process according to the current embodiment can be performed batch-wise, semi-continuously or continuously. Due to the stability improvement of the flux composition, the process is suitable for production of batches. Semi-continuous or continuous processes also benefit from the quality and stability improvements of the flux composition, as unplanned production often will have less tendency to lead to clogged lines or unstable quality of the product.

Embodiment E2 of the present invention concerns a process for the manufacture of a flux composition, comprising
a. Mixing at least one binder and at least one dispersion agent, wherein a temperature of equal to or lower than 70° C., preferably equal to or lower than 60° C. and even more preferably of equal to or lower than 50° C. is maintained during the mixing.
b. Optionally homogenizing the mixture obtained by step a. while controlling the temperature of the mixture such that a temperature of equal to or lower than 70° C., preferably equal to or lower than 60° C. and even more preferably of equal to or lower than 50° C. is maintained
c. Adding at least one flux to the mixture obtained by the foregoing steps at a temperature of equal to or lower than 70° C., preferably equal to or lower than 60° C. and even more preferably of equal to or lower than 50° C.
d. Homogenizing the mixture obtained by step c) while controlling the temperature of the mixture such that a temperature of equal to or lower than 70° C., preferably equal to or lower than 60° C. and even more preferably of equal to or lower than 50° C. is maintained.

According to this embodiment, the process comprises a step a., in which least one binder and at least one dispersion agent are mixed, wherein a temperature of equal to or lower than 70° C., preferably equal to or lower than 60° C. and even more preferably of equal to or lower than 50° C. is maintained during the mixing. The binder is added in step a. either as binder or as binder composition. Generally, a temperature of equal to or higher than 0° C., preferably equal to or higher than 5° C. and even more preferably of equal to or higher than 10° C. is maintained in step d). In one aspect, it is preferred that a temperature of from 10° C. to 50° C. is maintained in step a. The temperature is achieved by active cooling or heating, or by passively letting the mixture adapt to a temperature within the given range. Often, the binder, or binder composition, is added to the dispersion agent. The amount of dispersion agent and binder is consistent with the amount of dispersion agent and binder of embodiment El. The at least one binder can also be used in the form of a binder composition comprising the at least one binder and a dispersion agent. The mixing is performed with stirrers consistent with the stirrers identified in embodiment El. In an optional step b., the mixture obtained by step a. is homogenized. while controlling the temperature of the mixture such that a temperature of equal to or lower than 70° C., preferably equal to or lower than 60° C. and even more preferably of equal to or lower than 50° C. is maintained. Generally, a temperature of equal to or higher than 0° C., preferably equal to or higher than 5° C. and even more preferably of equal to or higher than 10° C. is maintained in step d). In one aspect, it is preferred that a temperature of from 10° C. to 50° C. is maintained in step b. The temperature is achieved by active cooling or heating, or by passively letting the mixture adapt to a temperature within the given range. In this step, the stirrer used in step a. can be employed. In another aspect, it can be advantageous to employ a different stirrer in step b. compared to the stirrer employed in step a. In one aspect, a stirrer which does not exert shear force is preferred in step b. Stirrers and preferred stirrers are generally consistent with those in embodiment E1. The embodiment further comprises step c., wherein at least one flux is added to the mixture obtained by the one or more foregoing steps wherein a temperature of equal to or lower than 70° C., preferably equal to or lower than 60° C. and even more preferably of equal to or lower than 50° C. is maintained during the addition. A temperature of equal to or lower than 30° C. is most particularly preferred. Generally, a temperature of equal to or higher than 0° C., preferably equal to or higher than 5° C. and even more preferably of equal to or higher than 10° C. is maintained in step d). In one aspect, it is preferred that a temperature of from 10° C. to 50° C. is maintained in step c. In an even more preferred aspect, a temperature of from 10° C. to 30° C. is maintained in step c. The temperature is achieved by active cooling or heating. In this step, the stirrer used in step a. and/or step b. can be employed. In another aspect, it can be advantageous to employ a different stirrer in step a. and/or b. The most preferred stirrer in step c. is a stirrer operating according to the rotor-stator-principle. The amount of flux added to in step c. is consistent with the amount described above. In a step d., the mixture obtained by step c. is homogenized while controlling the temperature of the mixture such that a temperature of equal to or lower than 70° C., preferably equal to or lower than 60° C. and even more preferably of equal to or lower than 50° C. is maintained. A temperature of equal to or lower than 30° C. is most particularly preferred. Generally, a temperature of equal to or higher than 0° C., preferably equal to or higher than 5° C. and even more preferably of equal to or higher than 10° C. is maintained in step d). In an even more preferred aspect, a temperature of from 10° C. to 30° C. is maintained in step d. The temperature is achieved by active cooling or heating. In this step, the stirrer used in step a. and/or step b and/or step c. can be employed. In another aspect, it can be advantageous to employ a different stirrer in step a. and/or b and/or c. The most preferred stirrer in step d. is a stirrer operating according to the rotor-stator-principle. Any additives, such as surfactants, thixotropic agents or suspension stabilizers, may be comprised in the dispersion agent, in the binder or binder composition or may be added separately in any of steps a., b., c. and/or d. The content of flux, dispersion agent, binder, optionally solvent and additives, is consistent with the amounts described above. After or during step d., the content of binder, binder composition, dispersion agent and/or solvent may be adjusted by addition of discrepant amounts to achieve the final content of the foregoing. In one aspect of the present invention, one or more solid additives are added to the mixture during the process. Such a solid additive can, for example, be another flux which modulates the brazing characteristics of the flux composition, for example a cesiumaluminumfluoride complex or a lithium compound. The solid additive can be added to the process as a solid, or as dispersion in a suitable dispersion agent, which is the same as described above. Preferably, the solid additive is added in the process in the form of a dispersion, even more preferably wherein the dispersion has been manufactured using a stirrer with rotor-stator-principle. The solid additive or its dispersion can be added before, during or after each of steps a. to d., as long as the temperature is not exceeded as defined above during and after addition of the binder or binder composition. It is important that the temperatures as described above are not exceeded once the binder or binder composition has entered the mixture. It should be noted that wherever in the process, mixing occurs, it is preferred to have any mixing step or any part of a mixing step performed by using a stirrer exerting shear force or a wet milling step. In one aspect, the process can include another step wherein, after addition of all components, and finalized mixing, the composition is filtered, for example through a 300 mesh filter. In one aspect, during the one or more mixing or homogenization steps, care should be taken that as little air as possible if mixed into the mixture in order to avoid foam. Due to the stability improvement of the flux composition, the process is suitable for production of batches. Semi-continuous or continuous processes also benefit from the quality and stability improvements of the flux composition, as unplanned production often will not lead to clogged lines or unstable quality of the product.

The invention further concerns a process for soldering, welding or, in particular, brazing of aluminum or aluminum alloy parts, wherein a flux composition manufactured by the process according to the invention is applied to at least one part of aluminum parts to be joined, in particular brazed, the aluminum parts are dried, assembled and heated to a temperature suitable for soldering, welding or, in particular, brazing the aluminum parts. More particularly, the invention concerns a process for brazing of aluminum or aluminum alloy parts, which comprises

a) coating the parts at least partially with the flux composition manufactured according to the process according to the present invention;

b) optionally drying the at least partially coated parts;

In another embodiment, the process further comprises:

c) assembling the at least partially coated parts;

d) heating the assembled, at least partially coated parts to a temperature sufficiently high to braze the at least partially coated parts;

e) brazing the at least partially coated parts;

f) optionally cooling the brazed parts.

The flux composition may be painted, printed, for example by pad printing or tampon printing (tampography), sprayed or be applied by dipping of the parts to be brazed into the composition in step a). The optional drying of the parts to which the composition was applied may be a physical or a chemical drying. The temperature which is needed for brazing depends on the aluminum or aluminum alloys from which the parts to be brazed are made and/or fillers and other brazing additives, as well as the brazing method (for example torch brazing or furnace brazing), and is known to the person skilled in the art. Often, the brazing temperature is from 420° C. to 650 ° C., more preferably the temperature is equal to or higher than 540° C. and equal to or lower than 650° C. In one embodiment, the brazing is performed under a controlled atmosphere, also known as CAB technique. Preferably, step c) and/or d) of the brazing process described above are performed in the presence of a protective gas containing equal to or more than 75% by volume of at least one gas selected from the group consisting of helium, nitrogen, argon and xenon. The brazed parts optionally are cooled, either actively or passively. In one aspect, prost-brazing treatment is applied, for example by heating the brazed parts, or by applying an additional layer, such as a hydrophobic layer, to the brazed parts. In one aspect, the flux composition manufacturing process steps are part of the brazing process, meaning that the flux manufacturing process and the brazing process are performed essentially subsequently, preferably in direct proximity or the same plant.

In one embodiment, the invention concerns a composition comprising at least one flux and a dispersion agent, wherein the composition was treated by a stirrer exerting shear force. In a particular aspect, the composition which was treated by a stirrer exerting shear force consists of at least one flux and a dispersion agent.

The invention also concerns a process for welding of aluminum or aluminum alloy parts, wherein a flux composition manufactured by the process according to the invention is applied to at least one part of aluminum or aluminum alloy parts to be welded, the aluminum or aluminum parts are dried, assembled and heated to a temperature suitable for welding the aluminum or aluminum alloy parts.

The invention also concerns a process for soldering of aluminum or aluminum alloy parts, wherein a flux composition manufactured by the process according to the invention is applied to at least one part of aluminum or aluminum alloy parts to be soldered, the aluminum or aluminum parts are dried, assembled and heated to a temperature suitable for soldering the aluminum or aluminum alloy parts.

The invention also concerns metal, in particular aluminum or aluminum alloy, parts which at least partially coated with at least one or more flux compositions manufactured by the process according to any one of the foregoing embodiments. In another aspect, invention also concerns assemblies which are assembled from two or more aluminum or aluminum alloy parts at least partially coated with at least one or more flux compositions manufactured by the process according to any one of the foregoing embodiments.

The invention further concerns, in particular, a brazed metal object which is obtainable according to the brazing process described above preferably a part of a cooler for stationary or mobile refrigeration equipment, such as air conditioning systems, or of a stationary heat exchanger.

The examples which follow are intended to illustrate the present invention without, however, limiting the scope thereof.

### EXAMPLE 1

193.75 kg demineralized water are stirred by a pitch blade turbine and 150 kg of Nocolok (R) flux is added in three portions. The mixture is passed through a colloid ball mill and fed into a 700 L tank with a temperature controlled jacket. The mixture is adjusted to 28° C., and a binder composition containing 25 kg polyurethane binder and 131.25 kg demineralized water is added while the mixture is stirred using a pitch blade turbine. During and after addition, the temperature in the tank is controlled at 28° C. The mixture is filtered through a 300 mesh sieve.

### EXAMPLE 2

188.5 kg demineralized water are stirred with a pitch blade turbine and 147.75 kg of Nocolok (R) flux is added in three portions. The mixture is passed through a colloid ball mill and fed into a 700 L tank with a temperature controlled jacket. The mixture is adjusted to 28° C., and a binder composition containing 25 kg polyurethane binder and 131.25 kg demineralized water is added while the mixture is stirred using a pitch blade turbine. During and after addition, the temperature in the tank is controlled at 28° C. To the mixture, a mixture of 2.25 kg CsAlF4 and 5.25 kg demineralized water, which have been treated for 5 minutes with an ultra turrax and temperature-adjusted to 28° C., are added to the mixture in the tank. The mixture is homogenized using a pitch blade turbine at 28° C., and filtered through a 300 mesh sieve.

### EXAMPLE 3

322 kg demineralized water are stirred in a 700 l tank with a pitch blade turbine, and 150 kg Nocolok (R) are added in 3 portions. The mixture is homogenized with a rotator-stirrer-stirrer. The temperature is adjusted to 27° C., and, stirring with a pitch blade turbine, 27.7 kg of a binder composition (36.6 weight % polyester polyurethan, 62,7 weight % demineralized water, 0.5 weight % siloxane surfactant, 0.2 weight % defoamer on polysiloxane basis) are added, while a temperature of 27° C. is maintained.

### EXAMPLE 4 (Comparative)

322 kg demineralized water are stirred in a 700 l tank with a pitch blade turbine, and 150 kg Nocolok (R) are added in 3 portions. The mixture is homogenized with a rotator-stator-stirrer. The temperature reaches 55° C. 27.7 kg of a binder composition (36.6 weight % polyester polyurethan, 62,7 weight % demineralized water, 0.5 weight % siloxane surfactant, 0.2 weight % defoamer on polysiloxane basis) are added immediately while stirring with the rotator-stator-stirrer, and a temperature of 53° C. is observed.

### Stability Observations:

The flux compositions of example 1-3 display very good stability, settling behaviour and homogeneity after storage for 48 hours at room temperature. The flux composition of example 4 displays a certain degree of phase separation, clogging and uneven thickness distribution (visual inspection, apparent “partial gelling/polymerization”) after storage for 48 hours at room temperature.

### Application of Flux Composition to Aluminum Parts

The flux compositions of examples 1-3 display a good paintability (machine painting) on aluminum parts, also after 48 hours of storage. Flux composition of example 4 displays some clogging in the paint flux apparatus, and uneven paint flux distribution on the aluminum parts.

1. A process for the manufacture of a flux composition, comprising at least one binder, at least one dispersion agent and at least one flux, the process comprising maintaining a temperature of equal to or lower than 70° C. during and after addition of the binder.

2. The process for the manufacture of a flux composition according to claim 1, comprising
a) Mixing at least one flux and at least one dispersion agent
b) Homogenizing the mixture obtained by step a)
c) Controlling the temperature of the mixture obtained by step b) such that a temperature of equal to or lower than 70° C., is achieved and maintained
d) Adding at least one binder to the mixture obtained by the foregoing steps at a temperature of equal to or lower than 70° C.

3. The process for the manufacture of a flux composition according to claim 1, comprising
a. Mixing at least one binder and at least one dispersion agent, wherein a temperature of equal to or lower than 70° C. is maintained during the mixing,
b. Optionally homogenizing the mixture obtained by step a. while controlling the temperature of the mixture such that a temperature of equal to or lower than 70° C. is maintained
c. Adding at least one flux to the mixture obtained by the one or more foregoing steps at a temperature of equal to or lower than 70° C.
d. Homogenizing the mixture obtained by step c) while controlling the temperature of the mixture such that a temperature of equal to or lower than 70° C. is maintained.

4. The process according to claim 1, wherein the at least one binder which is added is comprised in a binder composition.

5. The process according to claim 1, wherein the flux is a flux suitable for brazing of aluminum parts or aluminum alloy parts.

6. The process according to claim 1, wherein the at least one binder is selected from the group consisting of butyl rubbers, polyurethanes, resins, phthalates, polyacrylates, polymethacrylates, vinyl resins, epoxy resins, nitrocellulose, polyvinyl acetates, polysaccharide acetates, and polyvinyl alcohols.

7. The process according to claim 1, wherein the at least one dispersion agent is selected from the group consisting of water, alcohols, ketones, aliphatic hydrocarbons, ethers, and aromatic hydrocarbons.

8. The process according to claim 1, wherein the content of flux in the flux composition is equal to or greater than 0.75% by weight, and equal to or less than 45% by weight of the total weight of the flux composition.

9. The process according to claim 1, wherein the content of binder in the flux composition is equal to or greater than 0.1% by weight, and equal to or less than 40% by weight of the total weight of the flux composition.

10. The process according to claim 1, wherein in at least one of the steps wherein mixing is performed, a stirrer exerting shear force or a wet milling step is used for mixing.

11. A flux composition comprising a flux and a binder, obtained by the process according to claim 1.

12. A process for the manufacture of coated parts, the process comprising
a) coating the parts at least partially with the flux composition according to claim 11;
b) optionally drying the at least partially coated parts.

13. Coated metal parts at least partially coated with at least one flux composition according to claim 11.

14. A process for brazing coated metal parts according to claim 13, the process comprising
c) assembling the at least partially coated parts;
d) heating the assembled, at least partially coated parts to a temperature sufficiently high to braze the at least partially coated parts;
e) brazing the at least partially coated parts;
f) optionally cooling the brazed parts.

15. A brazed metal object, obtained according to the process according to claim 14.

16. The process according to claim 1, comprising maintaining a temperature of equal to or lower than 60° C. during and after addition of the binder.

17. The process according to claim 1, comprising maintaining a temperature of equal to or lower than 50° C. during and after addition of the binder.

18. The process according to claim 5, wherein the flux comprises at least one compound selected from the group consisting of potassium fluoroaluminate, cesium fluoroaluminate, potassium fluorozincate and potassium fluorosilicate.

19. The process according to claim 6, wherein the at least one binder is selected from the group consisting of polyurethanes.

20. The process according to claim 7, wherein the at least one dispersion agent is selected from the group consisting of polyhydric alcohols and water.
